(19) United States
(12) Patent Application Publication
(10) Pub. No.: US 2007/0248233 A1
(43) Pub. Date: Oct. 25, 2007

(54) Method and apparatus for dynamically adjusting the spectral content of an audio signal

(75) Inventors: J. Craig Oxford, Nashville, TN (US); D. Michael Shields, St. Paul, MN (US)

Correspondence Address: Christina Ezell, PO BOX 50475, Nashville, TN, 37205, US

(73) Assignee: Iroquois Holding Company

(21) Appl. No.: 11/653,510

(22) Filed: Jan. 16, 2007

Related U.S. Application Data
(63) Continuation-in-part of application No. 11/633,908, filed on Dec. 5, 2006.
(60) Provisional application No. 60/794,293, filed on Apr. 22, 2006.

(51) Int. Cl. H03G 3/00

(52) U.S. Cl. 381/61

(57) ABSTRACT

An electronic circuit for dynamically adjusting the spectral content of an audio signal. The circuit includes a constant current source, a output buffer amplifier and a biased inductor for introducing controlled amplitude asymmetry. This apparatus thus can be arranged to process an audio signal so as to introduce a predictable and controllable harmonic distortion that is negligible at small signal amplitudes and increases progressively at larger signal amplitudes.

This application claims the benefit of provisional patent application Ser. No. 60/794,293, filed Apr. 22, 2006 by the present inventors. This application is a CIP of Ser. No. 11/633,908 filed Dec. 5, 2006 by the present inventors.

### BACKGROUND OF THE INVENTION

### Field of Invention

The present invention involves an electronic circuit capable of improving the sound emanating from an audio playback system. Solid-state amplifiers can be made to sound as viscerally satisfying as vacuum tube amplifiers by providing an electronic circuit capable of introducing predictable and controllable harmonic distortion that increases with increased signal amplitude.

### BACKGROUND OF THE INVENTION

The reproduction of music recordings is typically performed by a chain of equipment consisting of at least a playback device for the type of recording at hand, an amplifier and a loudspeaker.

There is abundant anecdotal evidence that many listeners prefer that the music reproduction chain should include a vacuum-tube based amplifier, which should also be preferably single-ended (as opposed to push-pull). Other factors being equal, the performance of such an amplifier will be objectively inferior to almost any other commonly used vacuum-tube or solid-state push-pull or topologically symmetrical amplifier.

The stated subjective preference nevertheless remains. It is important to understand why this might be so. In the production of music whether by electric guitar or symphony orchestra, preferences about musical instruments are influenced by the harmonic structure of the sound, which they produce. This is a very fundamental aspect of timbre. Some orchestras will even limit the acceptable historical provenance of musicians' instruments based on the tonal qualities associated with particular periods of manufacture. This importance of harmonic structure pertains equally to reproduced music. The reproduction of music is certainly not the same thing as its original production and it might be hoped that in the ideal case the reproducing process would be merely a transparent vessel for the original sounds. Alas, this is not the case nor is it likely to be so in the foreseeable future. Refinement of the measured performance of reproducing equipment is not always accompanied by an audible result, which is musically convincing. There are many reasons why this might be the case. Some of these are discussed below having particular relevance to the harmonic structure of the reproduced sound.

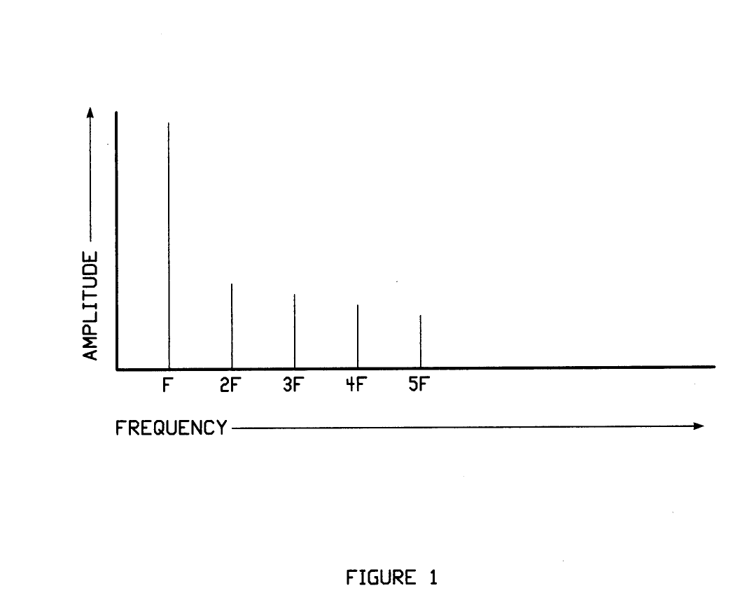

The objective inferiority of the single-ended vacuum-tube amplifier takes the form of higher numerical distortion. Measured as undesired harmonic content such an amplifier will exhibit a total harmonic distortion, THD, typically many times that of a symmetrical or push-pull amplifier. It should be pointed out that THD is a single-number expression, which does not quantify the spectral content of the distortion. Harmonic distortion consists of additions to the fundamental tone at new frequencies, which are integral multiples of the tone. For example an input signal to an amplifier at 1 kHz will result in an output signal which contains the original 1 kHz tone plus smaller amounts of 2,3,4 etc. kHz, as shown in FIG. 1. The THD is simply the square root of the sum of the squares of the harmonic amplitudes divided by the total amplitude. Multiplied by 100, the THD is usually stated in percent.

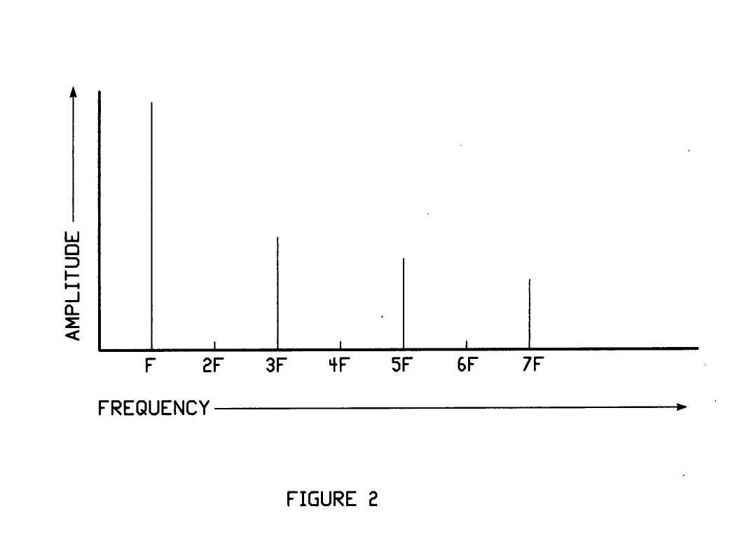

The use of this single-number rating provides a coarsely useful figure of merit for an amplifier but it may be seriously misleading because it does not qualitatively describe the distortion. Evidence of this is the often-stated listener preference for amplifiers with higher THD. Push-pull or symmetrical amplifiers are an example of this difficulty. The THD is reduced in these amplifiers because the topological symmetry causes the even-order harmonics (2^{nd}, 4^{th} etc.) to be cancelled. This results in an “empty” harmonic spectrum in which only the odd-order harmonics (3^{rd}, 5^{th} etc.) are present as shown in FIG. 2. In musical terms, the even harmonics are “consonant” and the odd harmonics are “dissonant”. Since in practical amplifiers the distortion is never zero, it would be better if the unavoidable residual distortion could be consonant rather than dissonant.

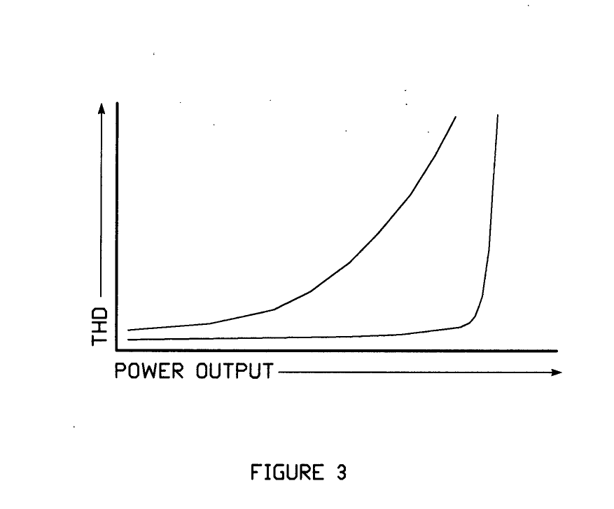

It is a further characteristic of amplifiers generally that the onset of whatever distortion occurs is progressive with signal amplitude. Extremely “clean” amplifiers may show very little distortion until they closely approach overload at which point the distortion increases almost catastrophically. Single-ended vacuum-tube amplifiers on the other hand have a very progressive distortion characteristic with signal amplitude. Push-pull vacuum-tube amplifiers are somewhere in between. Often this is related to the use of negative feedback, which is generally less in vacuum-tube designs and more in solid-state designs. The difference is illustrated in FIG. 3.

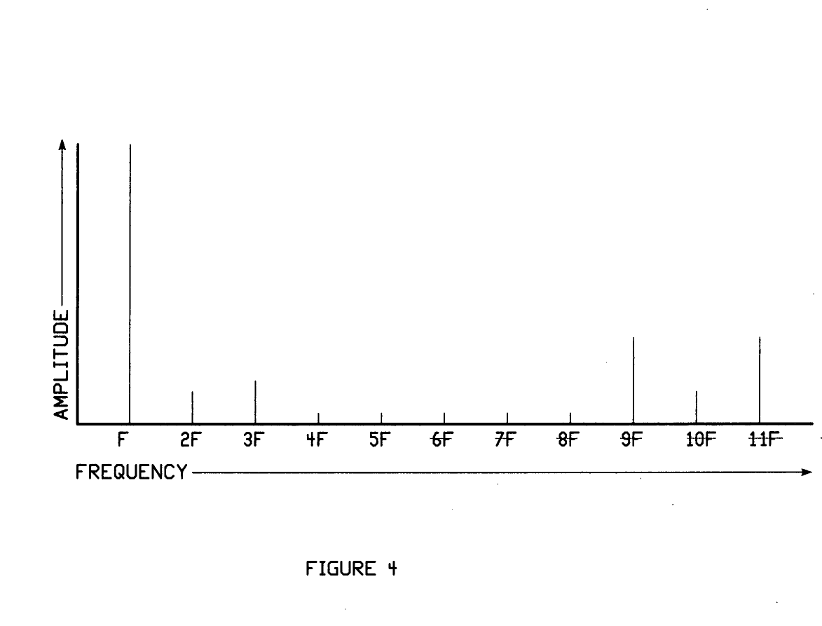

Another aspect of amplifiers, which affects the structure of the distortion, is the use of negative feedback. The application of negative feedback reduces the measured distortion in any amplifier. In practice, the reduction of distortion components by applying feedback does not uniformly reduce these components. The low-order, i.e. 2^{nd} and 3^{rd} harmonics will be reduced more effectively than the higher order harmonics. The consequence is that even though the THD is reduced the remaining distortion spectrum consists mainly of high order harmonics. This type of distortion is particularly unpleasant because it is spectrally far removed from the stimulus and therefore not masked by it. The confluence of subjectively disagreeable results occurs when symmetrical circuits are combined with large amounts of negative feedback. What results is a distortion spectrum, which consists almost entirely of odd high-order products as shown in FIG. 4. Perversely, these circuits usually produce the lowest measured THD.

There are several problems, which can be identified from the foregoing discussion. First, the use of vacuum tubes in modem equipment is undesirable if for no other reason than that reliable sources of supply do not exist. Second, the use of single-ended topologies in amplifiers, which must provide significant power output, is a tremendous disadvantage because of the necessity to operate such a circuit in class A bias. This condition of operation is unacceptably inefficient from both an environmental and engineering perspective. Third, the avoidance of negative feedback in a power amplifier results in a high source impedance of the output, which is contrary to the design requirements of most loudspeaker systems, which will be driven by the amplifier.

An optimum solution for the listener who expresses a preference for the single-ended vacuum tube amplifier “sound” as noted above could consist of two parts. First, a power amplifier which can employ moderate feedback to control the output impedance and which is of high enough power capability that the abrupt onset of overload is seldom or never reached in practical operation and second, a signal processing device which introduces a controlled distortion spectrum which arises progressively with amplitude and is monotonic with frequency. Monotonicity in this context means that each higher order of distortion has a smaller amplitude, so that the 2^{nd}, 3^{rd}, 4^{th} etc. harmonics become smaller in the same sequence. Such an arrangement can combine the audible attributes, which are sought along with the practical attributes of modem circuitry such as efficiency, adequate power output and longevity.

It should be pointed out that the addition or restoration of the low order harmonics as discussed above will have the effect of sharpening the rise of the leading edge of transient signals, this is analogous to edge enhancement in video. It has been observed that the rendering of the leading edge of transient signals is a key element in the perception of tone color or timbre and in the rapid identification of sounds.

### BACKGROUND OF THE INVENTION

### Prior Art

It should be pointed out that in the electric musical instrument industry as well as the recording industry there have been numerous attempts to emulate “tube” sound with solid-state circuits. A review of these attempts shows that they generally seem to misunderstand what they are trying to emulate. They mostly concern themselves with the notion of “soft clipping” in an attempt to render the overload behavior of high-feedback solid-state circuits less abrupt. But this approach only indirectly addresses the question of harmonic structure. Most of the prior art along these lines generally processes the signal symmetrically giving rise mainly to odd harmonics. Also, the processing usually takes the form of inverse-parallel diodes either acting as direct shunt elements across the signal path or as series elements in a feedback loop. The use of symmetrical clipping inside a feedback loop is directly contraindicated in view of the discussion above. Furthermore the use of only one or two diodes across their exponential “knee” makes the action too abrupt to approach the more gradual onset of distortion illustrated in the upper curve of FIG. 3.

Most of the prior art is implemented in a manner, which requires user adjustment of the operating parameters. The present invention can certainly be adjusted as will be shown, but properly implemented it is not necessary. Hard or soft clipping lie outside the intended region of operation although they are considered and provided for. Assuming the voltage gain of the downstream amplifier is known, the operation of the circuit can be coordinated with the overload point of the amplifier so as to optimize the interaction without further adjustment. Much of the need for adjustability in the prior art circuits is because of a narrow operating range and because they are intended as timbral special effects in the production as opposed to the reproduction of music.

Much audio is stored, distributed and processed in the digital domain. Regardless of this fact, the audio must ultimately be converted back to analog in order to be used. Many audio purists resist the digitization of audio, preferring pure analog sources such as LP recordings, which originate from analog master tapes. DSP will become a preferable implementation, in which event, the performance objectives of the present invention will remain unchanged. Anyone skilled in the art of DSP programming will be able to implement the present invention in digital recordings.

### BRIEF DESCRIPTION OF THE INVENTION

The instant apparatus seeks to restore the perceptual and emotional elements lost to technical processes. The instant apparatus is an electronic circuit, which can be arranged to process an audio signal so as to introduce a predictable and controllable harmonic distortion, which is negligible at small signal amplitudes and increases progressively at larger signal amplitudes. Further, no negative feedback is present in the signal path of this processor and the distortion spectrum is monotonic with frequency. In addition, the signal amplitude, which is lost in the process, can be restored without affecting the spectrum.

Recent developments in power amplifier technology have resulted in the availability of very high performance Class-D amplifiers, which operate with high efficiency and very low residual distortion. It is contemplated that an optimum use of the signal process to be described may be in conjunction with such Class-D amplifiers as well as the usual types of linear continuous-time amplifiers.

### DETAILED DESCRIPTION OF THE INVENTION

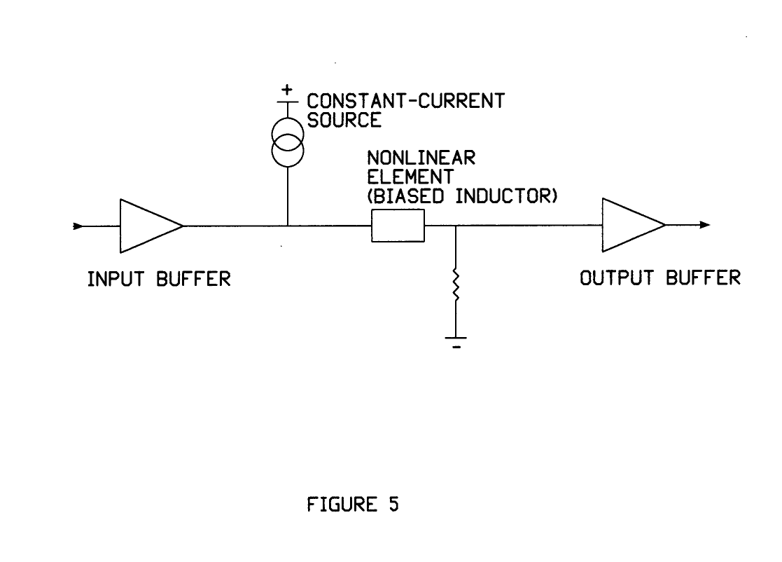

As shown in FIG. 5, the basic circuit consists of an input buffer, an output buffer, a constant-current source and a nonlinear element which consists of an inductor. The audio signal is AC-coupled at both ends of the nonlinear element and it is forward-biased by the constant-current source.

The circuit is intentionally unsymmetrical. As the audio signal voltage goes positive the core of the inductor begins to saturate which reduces its impedence at audio frequencies and causes an increase in the instantaneous value of the audio signal at its ouput. When the audio signal goes negative, this does not occur and the resulting asymmetry causes the generation of a monotonic harmonic spectrum.

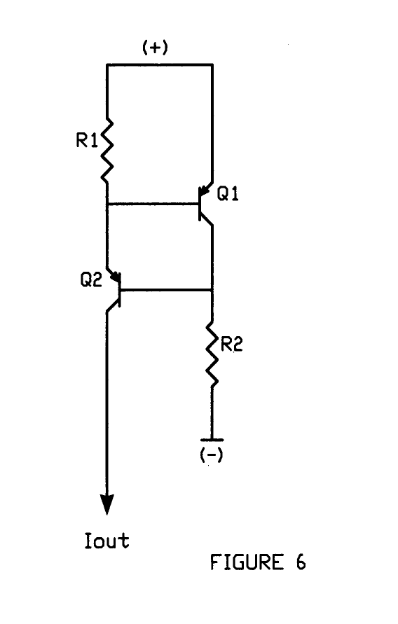

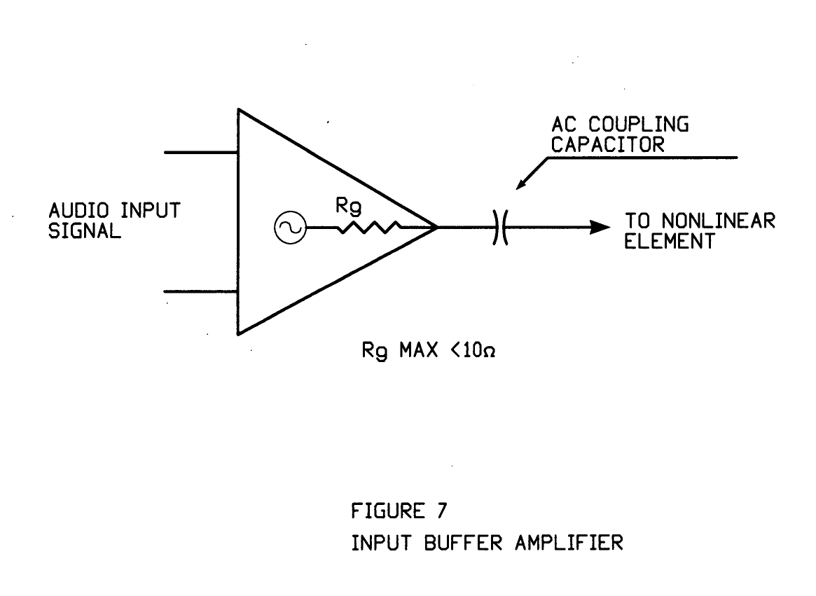

As shown in FIG. 6, the constant current source in a preferred embodiment is a ring source. Other topologies such as a Widlar current mirror can also be used. The influence of the current source on the circuit operation has been investigated and the ring source has been found to be optimum when implemented with transistors of high beta. This is because it maintains a very high AC impedance over the required frequency range and over the voltage range for which the rest of the circuit is useful. The current value, which is supplied by the constant-current source, is a basic operating parameter of the circuit. For a given range of signal amplitudes, the onset and quantity of harmonic distortion, which is generated, can be adjusted by varying the bias current from the constant-current source. The input buffer of the present invention is shown in FIG. 7. This stage is required in order to define the source impedance, which drives the inductor. Because the operation is based upon an instantaneous signal-dependent impedance change in the inductor, it follows that if the source resistance is too high the desired nonlinearity will be proportionally less and the intended circuit function will be diminished. In a preferred embodiment a source resistance should be held to less than 10 Ohms. If a driving amplifier with sufficiently low source resistance is available then the input buffer could eliminated. The output of the buffer must be AC-coupled to the input of the inductor with the coupling capacitor value large enough to prevent restriction of low frequencies due to the input impedance of the inductor. The exact value of the input impedance depends on the bias current supplied from the constant-current source. Anyone skilled in the art of circuit design will have no difficulty determining the coupling capacitor value.

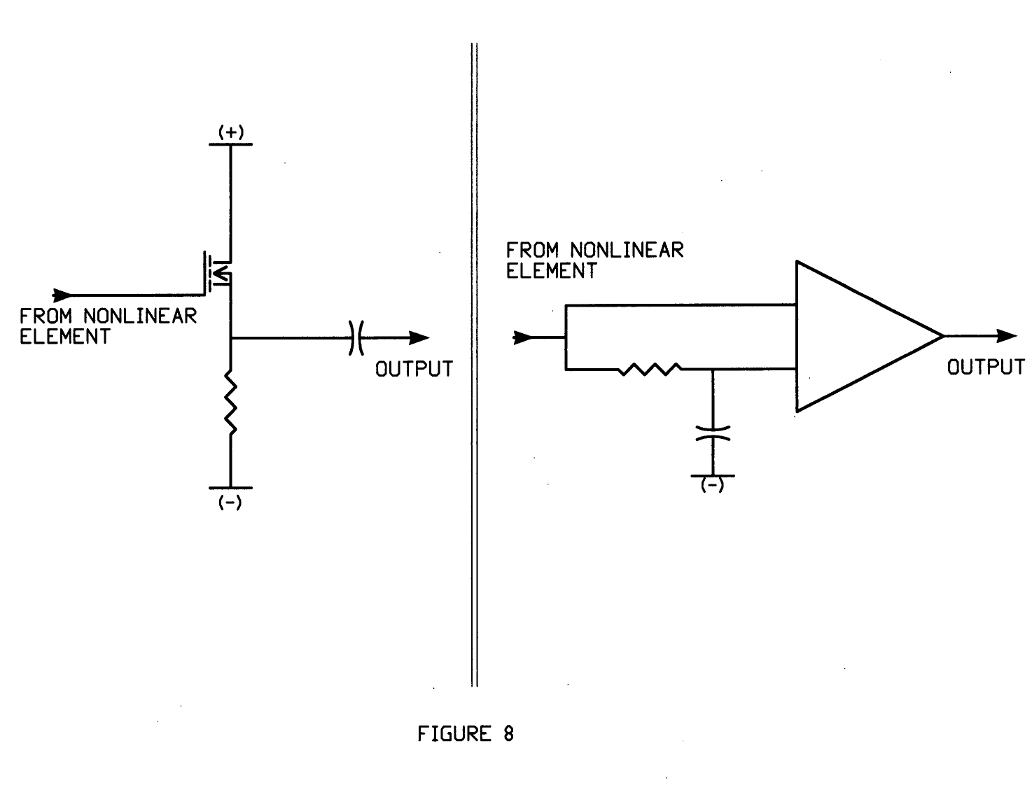

The output buffer of the present invention is shown in FIG. 8. This stage is required in order to prevent the downstream circuit from placing an undefined load on the inductor. In a preferred embodiment as shown, the buffer is a simple MOSFET source-follower, which is DC-coupled to the output of the inductor. Since the buffer will have a standing DC voltage on its source terminal it may be necessary to AC couple from the buffer to the following circuitry.

In an alternative implementation of the output buffer the signal may be returned to a ground-centered voltage by integrating the DC voltage at the output of the inductor at a sub-audio rate and subtracting it from the signal in a differential amplifier. Both embodiments are shown.

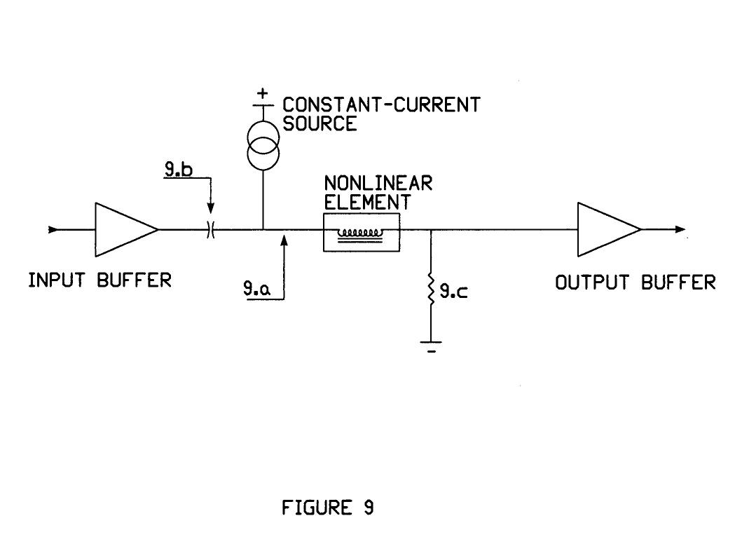

FIG. 9: The nonlinear inductor. The application of a constant-current bias to the inductor assures that it will produce the desired odd-even monotonic harmonic series as it approaches magnetic saturation. If the inductor is not biased then only odd harmonics are produced, which is not desirable. The constant-current source is shown in FIG. 6. An input buffer is as shown in FIG. 7. An output buffer is as shown in FIG. 8. Operation of the inductor is as follows: an alternating current flows through the inductor due to the application of an alternating voltage at 9.a from the buffer amplifier. The current flow is from the buffer amplifier via coupling capacitor 9.b through the inductor and through the load resistor 9.c. The resulting voltage across load resistor 9.c is taken as the output signal via the output buffer.

Current flow in an inductor produces a magnetizing force in the winding, which in turn produces a concentrated magnetic flux in the core. The total current is composed of the AC audio signal plus the DC constant-current. This causes more magnetic flux in the core when the AC signal is in the same direction as the DC bias, and less flux in the core when the AC signal is in opposition to the DC bias. Assuming the magnitudes of the currents are appropriately scaled, the core of the inductor will approach saturation more quickly for one polarity of the AC signal than for the other polarity. As the core of an inductor approaches saturation, the value of the inductance falls. Since the impedance of an inductor is directly proportional to the inductance, the series impedance of the signal path will vary asymmetrically through the signal cycle. The resulting asymmetry accomplishes the desired spectral alteration. The degree of asymmetry is directly proportional to the constant-current bias and may therefore be adjusted by changing the bias current. The rate of onset of the asymmetry is governed by the magnetic properties of the core, and by the range of AC signal amplitude. A core with a gradual magnetic saturation characteristic will provide a gradual increase in harmonic production. Such a core may be fabricated from powdered iron or Molypermalloy material. A core with an abrupt saturation characteristic will provide a more abrupt onset of harmonic production. Such a core may be fabricated from ferrite or amorphous metal.

The required inductance can be determined by considering the load resistance, R (item 9.c in FIG. 9). The impedance magnitude of an inductor varies directly with frequency. The result of this is that there will be a low-pass filter effect on the signal, i.e. the higher frequencies will be progressively attenuated. A criterion must be arbitrarily chosen for the allowable attenuation at the highest frequency of interest. In an audio application the attenuation should probably not exceed 1 dB ant 15 kHz. Given this requirement, the reactance of the inductor should be about 0.12 times the value of R. For example, if R=1000 Ohms, the inductive reactance, should be about 120 Ohms at 15 kHz. Since X_{L}=2πFL where:

X_{L}=Inductive reactance in Ohms

F=frequency in Hz

L=inductance in Henries (H)

the required inductance will be about 1.3 mH. If the inductance index A_{L} (in nH/n²) of the intended core is known, the number of turns (n) in the winding can be calculated as n=sqrt(L/A_{L}) remembering that for this equation L is expressed in nH.
The required bias current can be determined by the application of the relationship H=(nI)/(0.8Le) where:

H=magnetizing force in Oersteds

n=number of turns of wire in the winding

Le=effective magnetic path length of the core in cm

I=DC bias current in Amperes

and by the relationship B=uH where:

B=magnetic flux density in Gauss

u=average magnetic permeability of the core

Likewise, the required AC audio signal current can be determined by assuming that its peak value should be about 10 to 20 times the bias current. In the derivation of the inductance value above, the reactance at most audio frequencies can be neglected as the current will be mostly determined by the load resistance, R (item 9.c). The signal voltage, which will be required, is simply the product of the required RMS AC current and the load resistance. The RMS AC current can be safely taken to be 0.71× the peak AC current.

All of the above leads to an iterative calculation to determine the core size. Since the inductive reactance is small compared to the load resistance, there will not be much voltage developed across the winding. Since one expression for AC flux density is: B=(Vrms×10E8)/(4.44 nFA_{E}) where:

Vrms=applied AC voltage across the winding in Volts

n=number of turns

F=frequency of the applied AC voltage in Hz

A_{E}=effective magnetic cross-sectional area of the core in square cm

it would appear that the cross-section of the core is important. In fact, the applied voltage across the winding is due to the AC current times X_{L}, and will be small. On the other hand, since B=uH as above, in this case H is due to ΔI and ΔI=the RMS value of the peak AC signal current derived above (Ipkac). H=(nIpkac)/(0.8Le). The total magnetizing force will be the sum of H due to the DC bias current and H due to the AC signal current. Thus the effective magnetic path length of the core dominates. The resulting total flux density, B, should approach the rated saturation flux density for the core material at the highest AC signal level, which is to be processed. In a preferred embodiment, the physical implementation of the inductor should employ a toroidal core in the case of Molypermalloy, powdered iron or amorphous metal, or a pot core in the case of ferrite. This construction will give the best immunity to external magnetic fields, which could otherwise induce extraneous noise.

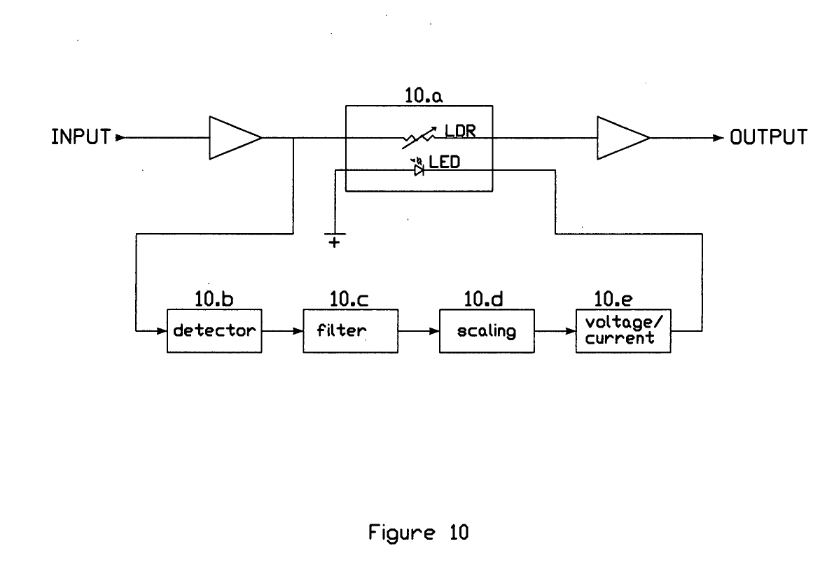

FIG. 12 shows a circuit, which can be added to the signal path after the spectral modification circuit, described above to counteract an undesired property of either the diode string or the inductor implementation of the nonlinear element. The desired asymmetry is imparted to the audio signal by effectively slightly “squashing” or “stretching” one polarity of the signal relative to the other. The net effect is a slight loss of energy at high signal levels compared to an unprocessed signal. Although the action is electrically instantaneous in the time domain, it is perceived in listening as an average loss of dynamics in loud passages. To counteract this effect, the added item in FIG. 10 is a signal expander. In an expander, the gain is proportional to the signal, i.e. the louder it gets, the louder it gets. In the instant invention, the expansion ratio is quite small being on the same order as the compression due to the nonlinear processes described above. This expander circuit responds to the average amplitude of the signal and operates with electrical symmetry. The result is that the average dynamic compression due to the nonlinear processes is compensated, but the asymmetry is not removed. Therefore the harmonic spectrum shaping is preserved and the dynamic energy is restored.

It should be noted that this technique can also be used to compensate the dynamic compression, which occurs in some loudspeakers due to heating of the voice-coil. In this application the circuit could be used separately or combined with spectral modification circuits of FIG. 9.

In a preferred embodiment the variable gain element, 10.a, is current-controllable and consists of a co-packaged light source and light dependent resistor (LDR). The LDR resistance varies inversely to the illumination from the light source which is typically a light emitting diode (LED) but which can also be an incandescent or electroluminescent device. In the case of the LED, the resistance value of the LDR will be inversely proportional to the current through the LED. The signal detector, 10.b can detect either the average or the root-mean-square value of the input signal. Average detection is done with a precision rectifier circuit well known in the art, the output of which is averaged in a resistor-capacitor network with a time constant appropriate to the desired speed of operation. If the detector has low output impedance and a circuit with high input impedance buffers the voltage on the capacitor, then the attack and release times of the circuit will be symmetrical. Typical attack and release times are on the order 50 milliseconds. This is a sufficient arrangement for most applications. RMS (root-mean-square) detection can also be used but has been found to be subjectively less effective than average detection. Peak detection is also possible as a variation of the precision rectifier circuit using well-known circuit design techniques. It can be argued that peak detection may be more appropriate since it is the signal peaks, which need to be “uncompressed”. Whatever detection method is used, the result must be post-filtered, 10.c to achieve the desired slow time constants. The post filtered voltage from the detector circuit is buffered and scaled as required, 10.d to control the variable gain element, 10.a Where the variable gain element is current-controlled, the voltage from the detector may converted to a current, 10.e using well known techniques.

1. An electronic circuit for processing an audio signal for introducing predictable and controllable harmonic distortion that increases with increased signal amplitude, said electronic circuit comprising an input buffer, an output buffer, a constant current source and a non-linear element.

2. The electronic circuit of claim 1 wherein said non-linear element comprises semiconductors.

3. The electronic circuit of claim 1 wherein said non-linear element comprises a DC biased inductor.

4. The electronic circuit of claim 1 wherein said audio signal is AC-coupled at both ends of the non-linear element and is forward-biased by said constant-current source.

5. The electronic circuit of claim 1 wherein said constant current source comprises a ring source.

6. The electronic circuit of claim 1 wherein said constant current source comprises a Widlar current mirror.

7. The electronic circuit of claim 1 wherein the quantity of harmonic distortion generated by said circuit is adjustable by varying the bias current from said constant current source.

8. The electronic circuit of claim 3 further comprising an input buffer AC-coupled to the input of said inductor

9. The electronic circuit of claim 8 wherein said input buffer is AC-coupled to the input of said inductor with a coupling capacitor of sufficient value to substantially prevent restriction of low frequencies due to the input impedance of the inductor.

10. The electronic circuit of claim 3 further comprising an output buffer.

11. The electronic circuit of claim 10 wherein said output buffer comprises a MOSFET source-follower DC-coupled to the output of said inductor.

12. The electronic circuit of claim 1 wherein said non-linear element comprises an inductor.

13. The electronic circuit of claim 12 wherein said inductor is provided with a constant-current bias.

14. The electronic circuit of claim 12 wherein higher frequencies passing through said circuit are progressively attenuated, said attenuation not to exceed approximately 1 dB at 15 KHz.

15. The electronic circuit of claim 1 wherein a signal expander is added to said circuit

16. A method for dynamically adjusting the spectral content of an audio signal, which increases the harmonic content through the systematic introduction of amplitude asymmetry.

17. The method of claim 16 in which the amplitude asymmetry creates both even and odd order harmonics.

18. The method of claim 16 in which the asymmetry is controlled so that the resulting harmonic spectrum is low-order and monotonic.

19. An apparatus for dynamically adjusting the spectral content of an audio signal comprising a constant current source, an output buffer amplifier and a biased inductor to produce a controlled asymmetry of the transfer characteristic.

20. The apparatus as set forth in claim 19 wherein said electronic circuit further comprises an input buffer amplifier.

21. The apparatus as set forth in claim 19 wherein the constant current source is adjustable.

22. The apparatus of claim 19 wherein the output buffer amplifier is offset to eliminate DC offset of the biased inductor.

23. An apparatus for dynamically adjusting the spectral content of an audio signal comprising a constant current source, an input buffer amplifier and a biased inductor to produce a controlled asymmetry of the transfer characteristic.

24. The apparatus as set forth in claim 23 wherein said constant current source is adjustable.

25. The apparatus set forth in claim 23 incorporated within the signal path of a power amplifier

26. The apparatus as set forth in claim 23 incorporated within the signal path of a power amplifier.

27. The apparatus as set forth in claim 26 wherein said power amplifier comprises a linear amplifier.

28. The apparatus as set forth in claim 26 wherein said amplifier comprises a switching, or Class D amplifier.

29. The apparatus as set forth in claim 26 where in said amplifier comprises a tracking, or Class H amplifier.

30. An apparatus for dynamically adjusting the spectral content of an audio signal comprising a constant current source and a biased inductor to produce a controlled asymmetry of the transfer characteristic.

31. The apparatus of claim 30 wherein said constant current source is adjustable.

32. The apparatus of claim 30 further comprising an input buffer amplifier.

33. The apparatus of claim 30 further comprising an output buffer amplifier offset to eliminate the DC offset of said biased inductor.

34. The apparatus of claim 30 further comprising an output buffer amplifier.

35. The apparatus of claim 30 incorporated within the signal path of the power amplifier.

36. The apparatus of claim 35 wherein said power amplifier is a linear amplifier.

37. The apparatus of claim 35 wherein said power amplifier is a switching or class D amplifier.

38. The apparatus of claim 35 wherein said power amplifier is a tracking or class H amplifier.

39. An apparatus for adjusting the average amplitude of an audio signal by expansion comprising a variable gain amplifier or a variable attenuator, a signal detector and a control conditioning circuit.

40. The apparatus as set forth in claim 39 wherein variable gain amplifier is characterized as having its gain controlled by a voltage or current control signal.

41. The apparatus as set forth in claim 39 wherein said variable attenuator is controlled by a voltage or current control signal.

42. The apparatus as set forth in claim 39 wherein said signal detector is responsive to the average or peak value of the input signal.

43. The apparatus as set forth in claim 39 wherein said signal detector is responsive to the RMS value of the input signal.

44. The apparatus as set forth in claim 39 characterized as having an expansion ratio that is numerically low.

45. The apparatus as set forth in claim 39 wherein said conditioning circuit is characterized as having adjustable parameters with respect to integration time and expansion ratio.

46. The apparatus as set forth in claim 39 incorporated within the signal path of a spectral content processor.

47. The system as set forth in claim 39 incorporated within the signal path of a power amplifier.

48. The system as set forth in claim 47 wherein said power amplifier is a linear amplifier.

49. The system as set forth in claim 47 wherein said power amplifier is a switching, or Class D amplifier.

50. The system as set forth in claim 47 wherein said power amplifier is a tracking, or Class H amplifier.

51. The system as set forth in claim 39 incorporated as an integral part of a system which comprises a spectral content processor and n audio power amplifier.
